(19) United States
(12) Patent Application Publication
(10) Pub. No.: US 2010/0103749 A1
(43) Pub. Date: Apr. 29, 2010

(54) SEMICONDUCTOR MEMORY DEVICE

(75) Inventor: YUKI HOSOE, TOKYO (JP)

Correspondence Address: YOUNG & THOMPSON, 209 Madison Street, Suite 500, Alexandria, VA, 22314, US

(73) Assignee: ELPIDA MEMORY, INC., TOKYO (JP)

(21) Appl. No.: 12/581,910

(22) Filed: Oct. 20, 2009

(30) Foreign Application Priority Data
Oct. 24, 2008 (JP) 2008-274212

(51) Int. Cl. G11C 7/10

(52) U.S. Cl. 365/189.05; 365/51

(57) ABSTRACT

A semiconductor memory device includes a memory cell region including memory cells that store data. An input buffer is disposed on one side of the memory cell region. On the other hand, an output buffer is disposed on another side opposite to the input buffer in the memory cell region.

### BACKGROUND OF THE INVENTION

1. Field of Invention

The present invention relates to a semiconductor memory device.

2. Description of the Related Art

FIG. 1 is a schematic diagram showing a chip layout of a semiconductor memory device according to related art. FIG. 1 shows an example of the chip layout of a DRAM (Dynamic Random Access Memory) equipped with a plurality of memory cell regions (four regions in FIG. 1).

The semiconductor memory device shown in FIG. 1 has a configuration wherein four memory cell regions 12 are disposed on the edge portions of chip 11 in a matrix state, and pads 13 for inputting and outputting are disposed in the vicinity of the center of chip 11. In the semiconductor memory device shown in FIG. 1, command circuit 14 including input buffers for temporarily holding commands or addresses input into the semiconductor memory device through pads, and data circuit 15 including input-output buffers for temporarily holding data input from and outputting data to each memory cell region 12 are disposed in the vicinity of the center of chip 11, respectively. The addresses are used for storing data in memory cell regions, or for selecting memory cells to read out data; and the commands include, for example, write commands for storing data in a selected memory cell, or read commands for reading out data from a selected memory cell.

According to the chip layout shown in FIG. 1, the connection between command circuit 14 and each memory cell region 12, and the connection between data circuit 15 and each memory cell region 12, can be implemented using similar wiring paths, respectively, by collectively disposing a plurality of input buffers 16 for inputting signals formed on the basis of commands or addresses input from the exterior, and by collectively disposing a plurality of output buffers 17 for writing data in memory cell MC or for outputting date read out from memory cell MC, in the vicinity of the center of chip 11 in each memory cell region 12. Therefore, each wiring can be efficiently laid out.

A chip layout wherein input-output pads 13, command circuit 14, data circuit 15 and the like are disposed in the vicinity of the center of chip 11; and a plurality of input buffers 16 and output buffers 17 are collectively disposed in the vicinity of the center of chip 11 in each memory cell region 12, are described, for example, in Japanese Patent Application Laid-Open No. 10-241363.

Also, the related art of the present invention includes a memory system described in Japanese Patent Application Laid-Open No. 2000-148656, and a master slice LSI described in Japanese Patent Application Laid-Open No. 08-236734.

In semiconductor memory devices of recent years, the area of the memory cell region has been enlarged with increases in memory capacities and bit numbers. Therefore, in the chip layout shown in FIG. 1, the difference between the lengths of wirings for connecting memory cells disposed in the vicinity of the center of the chip to the command circuit or to the data circuit and the lengths of wirings for connecting memory cells disposed in the vicinity of the ends of the chip to the command circuit or to the data circuit tends to be enlarged.

Furthermore, since higher frequencies are used in a clock for operating the semiconductor memory device in order to shorten time for writing and reading data, a problem of the generation of large skew (clock skew) is caused by the difference in the length of wirings.

FIG. 2 shows the state of operations from inputting commands for reading out data to the semiconductor memory device shown in FIG. 1 to reading out data from the memory cell corresponding to the commands. The memory cell (near end) used in the following description means a memory cell disposed in the vicinity of the center of the chip in the memory cell region that is disposed on the upper left of FIG. 1, and the memory cell (far end) means a memory cell disposed in the vicinity of the end of the chip in the memory cell region that is disposed on the lower right of FIG. 1.

As shown in FIG. 2, when a prescribed command (CMD) is input into the semiconductor memory device shown in FIG. 1, signals formed on the basis of the command are output from the input buffer (near end) corresponding to the memory cell (near end) at a time after a required time (X [ns]) has elapsed from the time when the command has been input.

Also when a required time (Y [ns]) has elapsed from the time when the command has been input into the semiconductor memory device, data read out from the memory cell (near end) is input into the output buffer (near end) corresponding to the memory cell (near end).

Furthermore, when a required time (Z [ns]) has elapsed from the time when the command has been input into the semiconductor memory device, data output from the output buffer (near end) is input into the data circuit.

In this case, at the time when Z [ns] has elapsed after the prescribed command (CMD) has been input, a control circuit (not shown) for generating data enable signals that indicate the establishment of the data is designed so that the data enable signals are supplied to the data circuit.

On the other hand, when a prescribed command (CMD) is input into the semiconductor memory device shown in FIG. 1, signals corresponding to the command are output from the input buffer (far end) corresponding to the memory cell (far end) at time X [ns]+α, wherein the above-described required time (X [ns]) is added to the wiring delay (α) corresponding to the difference between the distance from the command circuit to the above-described input buffer (near end) and the distance from the command circuit to the input buffer (far end).

Also, data read out from the memory cell (far end) is input into the output buffer (far end) corresponding to the memory cell (far end) after a command is input into the semiconductor memory device at time Y [ns]+α+β, wherein the above-described required time (Y [ns]) is added to the above-described wiring delay (α) and wiring delay (β) corresponding to the difference between the distance from the input buffer (near end) to the output buffer (near end) and the distance from the input buffer (far end) to the output buffer (far end).

Furthermore, data output from the output buffer (far end) is input into the data circuit after the command is input into the semiconductor memory device at time Z [ns]+α+β+θ, wherein the above-described required time (Z [ns]) is added to the above-described wiring delay (α), wiring delay (β) and wiring delay (θ) corresponding to the difference between the distance from the data circuit to the output buffer (near end) and the difference between the distance from the data circuit to the output buffer (far end).

In this case, when Z [ns]+α+β+θ has elapsed after the prescribed command (CMD) has been input, a control circuit (not shown) for generating data enable signals indicating the establishment of data is designed so that the data enable signals are supplied to the data circuit.

Therefore, in the semiconductor memory device according to the related art shown in FIG. 1, difference in α+β+θ (skew) is generated in the time from the time when the command (CMD) is input into the semiconductor memory device to the time when the data that is read out from the memory cell (near end) is input into the data circuit, and the time until the data read out from the memory cell (far end) is input into the data circuit.

The problem of skew generated from the semiconductor memory device according to the chip layout shown in FIG. 1 can be solved by, for example, a method wherein the operation speed (amount of delay) of transistors equipped with the input buffers and output buffers in memory cell regions is changed depending on the distance from the command circuit or the data circuit; or by a method wherein the amount of delay due to the wiring capacity is changed depending on the distance from the command circuit or the data circuit. Here, the operation speed (amount of delay) of transistors can be controlled by, for example, changing the gate size of transistors. The wiring capacity can be controlled by, for example, changing the wiring width.

However, since wirings are concentrated in the vicinity of the center of the chip in the chip layout shown in FIG. 1, there is a limit to the amount of clock skew that can be reduced by the above described methods so as to adjust the operation speed of the transistors or wiring capacity.

### SUMMARY

In one embodiment, there is provided a semiconductor memory device that includes a memory cell region including a plurality of memory cells that store data; an input buffer disposed on one side of the memory cell region and for providing signals based on address signals and command signals into the memory cells; and an output buffer disposed on another side opposite to the input buffer in the memory cell region and for outputting data read from a selected memory cell.

According to the semiconductor memory device as described above, wirings from input buffers to output buffer provided to each of the memory cells in the memory cell region can be designed to have almost the same length. Therefore, there is no necessity to dispose the folded wiring from a memory cell to an output buffer relative to the wiring from an input buffer to the memory cell. Therefore, the difference between the length of the wiring for connecting memory cells disposed in the vicinity of the center of the chip to the command circuit or the data circuit and the length of the wiring for connecting memory cells disposed in the vicinity of the end of the chip to the command circuit or the data circuit is reduced, compared with the semiconductor memory device according to the related art. As a result, skews generated by the difference in wiring lengths to memory cells can be further reduced compared with the semiconductor memory device according to the related art.

The above and other objects, features, and advantages of the present invention will become apparent from the following description with reference to the accompanying drawings, which illustrate examples of the present invention.

### BRIEF DESCRIPTION OF THE DRAWING

FIG. 1 is a schematic diagram showing a chip layout of a semiconductor memory device according to a related art;

FIG. 2 is a timing chart illustrating the operation of the semiconductor memory device shown in FIG. 1;

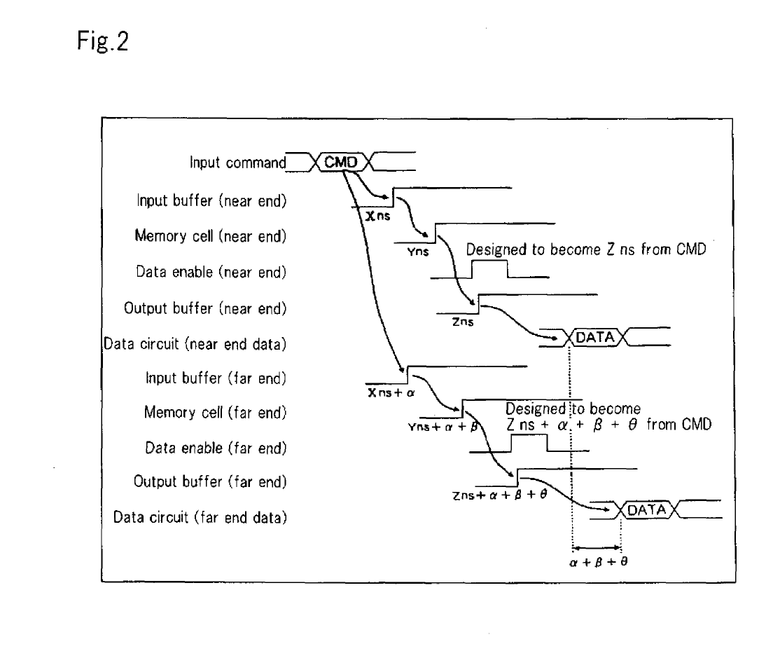

FIG. 3 is a schematic diagram showing an example chip layout of a semiconductor memory device according to a first embodiment;

FIG. 4 is a timing chart illustrating the operation of the semiconductor memory device shown in FIG. 3; and

FIG. 5 is a schematic diagram showing an example chip layout of a semiconductor memory device according to a second embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purposes.

### First Embodiment

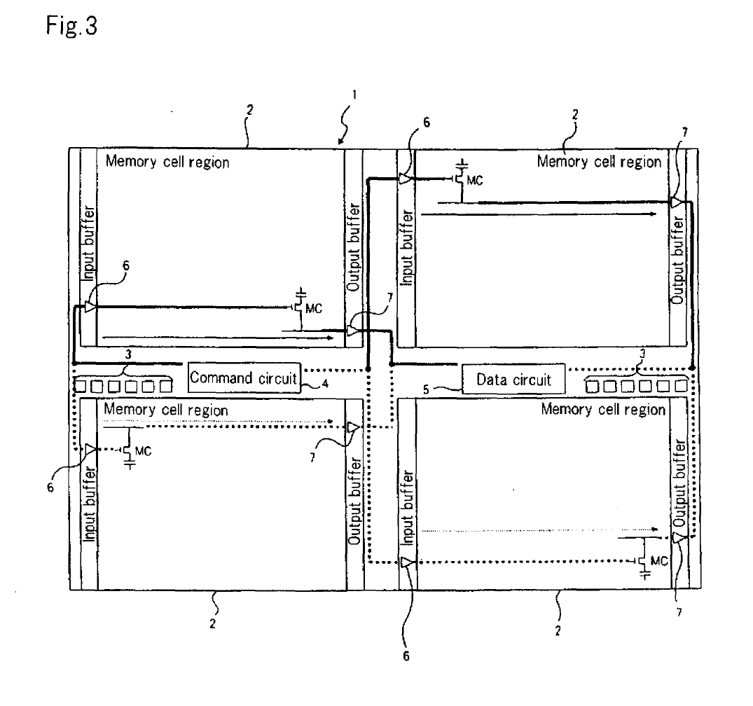

FIG. 3 is a schematic diagram showing an example chip layout of a semiconductor memory device according to a first embodiment.

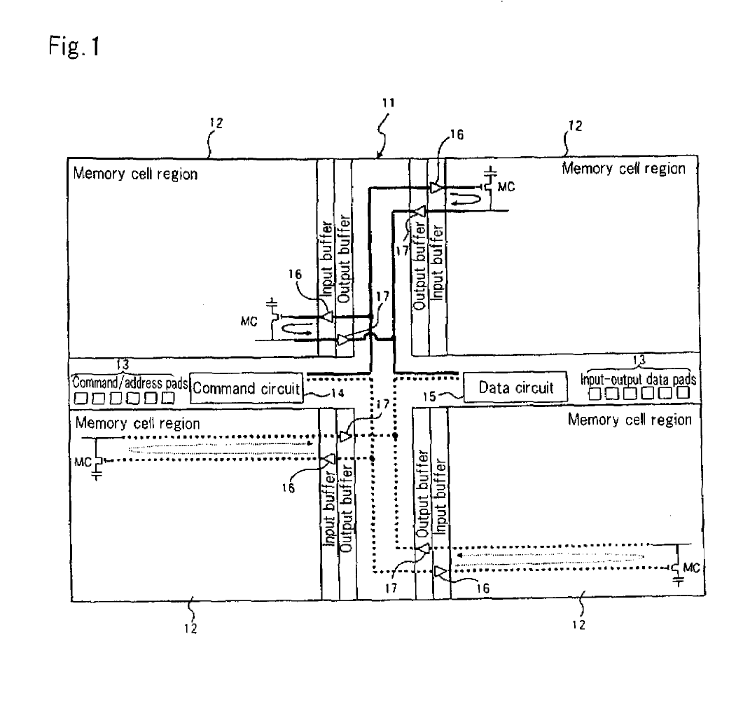

As shown in FIG. 3, the semiconductor memory device according to the first embodiment has a configuration wherein four memory cell regions 2 are disposed on the edge portions of chip 1 in a matrix state, and pads 3 for inputting and outputting are disposed in the vicinity of the center of chip 1, in the same manner as in the semiconductor memory device according to the related art shown in FIG. 1. Also in the vicinity of the center of chip 1 in the semiconductor memory device shown in FIG. 3, command circuit 4 including an input buffer for temporarily holding commands and addresses input in the semiconductor memory device, and data circuit 5 including an input-output buffer for temporarily holding data input in or output from each memory cell region 2 are disposed, respectively. However, the number of the memory cell regions 2 is not necessarily more than one, but may be any number as long as it is at least one.

As shown in FIG. 3, in the semiconductor memory device according to the first embodiment, a plurality of input buffers 6 for inputting signals formed on the basis of commands and addresses into memory cells MC are disposed on an end of each memory cell region 2, and a plurality of output buffers 7 for outputting data written in memory cells MC or read from memory cells MC are disposed in the locations facing input buffers 6 in memory cell region 2. Also in the semiconductor memory device according to the first embodiment, when a plurality of memory cell regions 2 are equipped, input buffer 6 and output buffer 7 of memory cell regions 2 are disposed in the identical locational relationship, respectively.

In the chip layout as shown in FIG. 3, a difference in wiring length from command circuits 4 to input buffers 6 is produced corresponding to the location of input buffers 6, and a difference in wiring length from output buffer 7 to data circuit 5 is produced corresponding to the location of output buffer 7.

However, in memory cell region 2, wiring from input buffer 6 to output buffer 7 that is provided corresponding to each memory cell MC can be almost linearly disposed, and there is no necessity to dispose the folded wiring from memory cell mc to output buffer 17 for the wiring from input buffer 16 to memory cell MC as the chip layout of the related art shown in FIG. 1.

Therefore, wirings from input buffer 6 to output buffer 7 that are provided corresponding to each memory cell MC can be designed to have almost the same length, and the difference between the length of wirings connecting memory cell MC disposed in the vicinity of the center of chip 1 and command circuit 4 or data circuit 5, and the length of wirings connecting memory cell MC disposed in the vicinity of the end of chip 1 with command circuit 4 and data circuit 5 can be reduced compared with the semiconductor memory device according to the related art shown in FIG. 1. Therefore, the skew generated by the difference in wiring length to memory cell MC can be reduced compared with the semiconductor memory device according to the related art shown in FIG. 1.

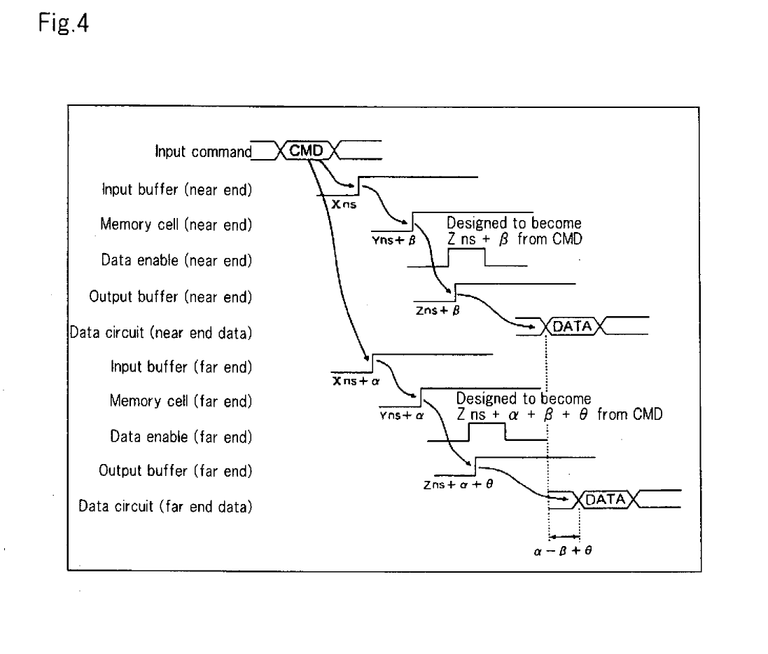

FIG. 4 is a timing chart illustrating the operation of the semiconductor memory device shown in FIG. 3.

In FIG. 4, the state of operation wherein commands for reading out data that is input to the semiconductor memory device shown in FIG. 3 and until the data is read out from memory cell MC corresponding to the commands is illustrated. The memory cell (near end) used in the following description shows memory cell MC disposed in the vicinity of the center of chip 1 in memory cell region 2 disposed on the upper left of FIG. 3; and the memory cell (far end) shows memory cell MC disposed in the vicinity of the end of chip 1 in memory cell region 2 disposed on the lower right of FIG. 3.

As shown in FIG. 4, when a prescribed command (CMD) is input into the semiconductor memory device shown in FIG. 3, signals formed on the basis of the command are output from the input buffer (near end) corresponding to a memory cell (near end) at the time when a required time (X [ns]) has elapsed.

Also, after the command has been input into the semiconductor memory device, the data read out from the memory cell (near end) is input into the output buffer (near end) corresponding to the memory cell (near end) at time Y [ns]+β, wherein the above-described required time (Y [ns]), and wiring delay (β) corresponding to the difference between the distance from the memory cell (near end) to the output buffer (near end) and the distance from the memory cell (far end) to the output buffer (near end) are added.

Furthermore, after the command has been input into the semiconductor memory device, data output from the output buffer (near end) is input into the data circuit at time Z [ns]+β wherein the above-described required time (Z [ns]) and the above-described wiring delay (β) are added.

In this case, a control circuit (not shown) for generating data enable signals is designed so that the data enable signals that indicate the establishment of data are supplied to the data circuit at time Z [ns]+β after the prescribed command (CMD) has been input.

On the other hand, when the prescribed command (CMD) is input into the semiconductor memory device shown in FIG. 3, signals are output from the input buffer (far end) corresponding to the memory cell (far end) corresponding to the command at time X [ns]+α, wherein wiring delay (α) corresponding to the difference between the distance from command circuit 4 to the input buffer (near end) and the distance from command circuit 4 to the input buffer (far end) is added to the above-described required time (X [ns]).

Data read out from the memory cell (far end) is input in the output buffer (far end) corresponding to the memory cell (far end) after the command is input into the semiconductor memory device, at time Y [ns]+β, wherein the above-described required time Y [ns] and the above-described wiring delay (α) are added. In the semiconductor memory device shown in FIG. 3, since the distance from the memory cell (near end) to the output buffer (near end) is substantially identical to the distance from the memory cell (far end) to the output buffer (far end), wiring delay (β) due to the difference in these wirings becomes zero.

Furthermore, data output from the output buffer (far end) is input into data circuit 5 after the command is input into the semiconductor memory device, at time Z [ns]+α+θ, wherein above-described required time (Z [ns]), the above-described wiring delay (α), and the wiring delay (θ) corresponding to the difference between the distance from data circuit 5 to the output buffer (near end) and the distance from data circuit 5 to the output buffer (far end).

In this case, a control circuit (not shown) for generating the data enable signals so that data enable signals that indicate the establishment of data are supplied to data circuit 5, at time Z [ns]+α+θ after the prescribed command (CMD) has been input.

Therefore, according to the semiconductor memory device shown in FIG. 3, the difference between the time after the command (CMD) has been input into the semiconductor memory device to the time when data read out from the memory cell (near end) is input into data circuit 5 and the time until the data read out from the memory cell (far end) is input into data circuit 5 becomes α−β+θ.

Therefore, it is known that skew generated by the difference in wiring length to memory cell MC can be reduced, compared with the semiconductor memory device according to the related art shown in FIG. 1.

### Second Embodiment

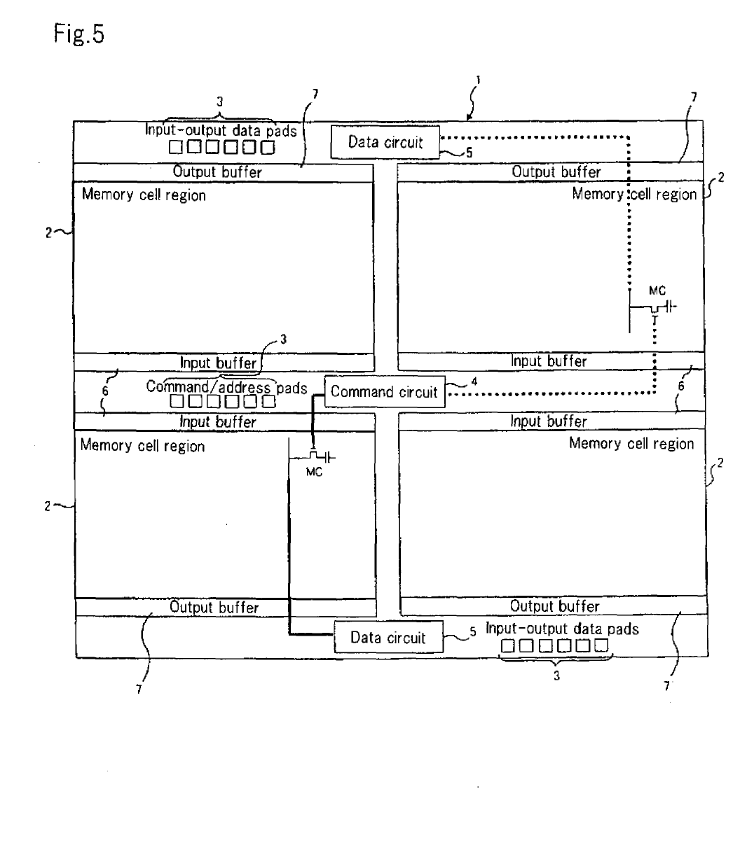

FIG. 5 is a schematic diagram showing an example of the chip layout of a semiconductor memory device according to a second embodiment.

As shown in FIG. 5, the semiconductor memory device according to the second embodiment has a configuration wherein command circuit 4 including input buffers for temporarily holding commands and addresses input into the semiconductor memory device, and pads 3 for inputting the commands and addresses are disposed in the vicinity of the center of chip 1; and data circuit 5 including input-output buffers for temporarily holding data input into and output from each memory cell region 2 and pads 3 for inputting and outputting the data are disposed in the end portions of chip 1.

In the semiconductor memory device according to the second embodiment, input buffers 6 for supplying signals generated on the basis of commands and addresses to memory cell MC are disposed on an end of each memory cell region 2; and output buffers 7 for writing data in memory cell MC or outputting data read out from memory cell MC are disposed in the location facing input buffers 6 in memory cell regions 2. However in the second embodiment, input buffers 6 in each memory cell region 2 are disposed in the vicinity of the center of chip 1, and output buffers 7 in each memory cell region 2 are disposed in the vicinity of the end of chip 1.

Even by the chip layout according to the second embodiment as shown in FIG. 5, since wirings from input buffers 6 to output buffers 7 corresponding to each memory cell MC can be designed to be almost the same wiring length in the same manner as in the first embodiment, the difference in the length of wirings between command circuit 4 and data circuit 5 and memory cell MC disposed in the vicinity of the center of chip 1, and the length of wirings between command circuit 4 and data circuit 5 and memory cell MC disposed in the vicinity of the end of chip 1 can be reduced, compared with the semiconductor memory device according to the related art shown in FIG. 1. Therefore, in the same manner as in the first embodiment, skew that is generated by difference in the wiring length to memory cell MC can be reduced, compared with the semiconductor memory device according to the related art shown in FIG. 1.

While the invention has been particularly shown and described with reference to exemplary embodiments thereof, the invention is not limited to these embodiments. It will be understood by those ordinarily skilled in the art that various changes in form and details may be made therein without departing from the spirit and scope of the present invention as defined by the claims.

What is claimed is:

1. A semiconductor memory device comprising a memory cell region for storing data, and
a command circuit disposed in the vicinity of the center of a chip where addresses and commands for selecting memory cells in said memory cell region are input, wherein
an input buffer inputting signals generated on the basis of said addresses and commands into said memory cells, is disposed on an end of said memory cell region, and
an output buffer outputting data read from said selected memory cell, is disposed on a location opposite to said input buffer in said memory cell region.

2. The semiconductor memory device according to claim 1, further comprising a data circuit disposed in the vicinity of the center of said chip, wherein an input-output buffer temporarily holding data input to or output from said memory cell region, is included.

3. The semiconductor memory device according to claim 2, comprising a plurality of said memory cell regions, wherein
a plurality of input buffers and output buffers each provided corresponding to said plurality of said memory cell regions are disposed in identical relationships relative to each memory cell region.

4. The semiconductor memory device according to claim 1, further comprising a data circuit disposed on an end portion of said chip, wherein an input-output buffer temporarily holding data input to or output from said memory cell regions, is included.

5. The semiconductor memory device according to claim 4, comprising a plurality of said memory cell regions, wherein
a plurality of input buffers each provided corresponding to said plurality of said memory cell regions are disposed in the vicinity of the center of the chip in each memory cell region; and a plurality of output buffers each provided corresponding to said plurality of said memory cell regions are disposed in the vicinities of the ends of the chip in each memory cell region.

6. A semiconductor memory device comprising:
a memory cell region including a plurality of memory cells that store data;
is a command circuit disposed in the vicinity of the center of a chip and for inputting address signals and command signals that select the memory cells in the memory cell region;
an input buffer disposed on one side of the memory cell region and for providing signals based on the address signals and command signals into the memory cells; and
an output buffer disposed on another side opposite to the input buffer in the memory cell region and for outputting data read from a selected memory cell.

7. The semiconductor memory device according to claim 6, further comprising a data circuit disposed on the vicinity of the center of the chip and including an input-output buffer temporarily holding data input to or output from the memory cell region.

8. The semiconductor memory device according to claim 6, comprising a plurality of the memory cell regions, wherein
a plurality of input buffers and output buffers each provided corresponding to the plurality of the memory cell regions are disposed in identical relationships relative to each memory cell region.

9. The semiconductor memory device according to claim 6, further comprising a data circuit disposed on an edge portion of the chip and including an input-output buffer temporarily holding data input to or output from the memory cell region.

10. The semiconductor memory device according to claim 9, comprising a plurality of the memory cell regions, wherein
a plurality of input buffers each provided corresponding to the plurality of the memory cell regions are disposed in the vicinity of the center of the chip in each memory cell region; and
a plurality of output buffers each provided corresponding to the plurality of the memory cell regions are disposed in the vicinities of the edges of the chip in each memory cell region.

11. A semiconductor memory device comprising:
a memory cell region including a plurality of memory cells that store data;
an input buffer disposed on one side of the memory cell region and for providing signals based on address signals and command signals into the memory cells; and
an output buffer disposed on another side opposite to the input buffer in the memory cell region and for outputting data read from a selected memory cell.

12. The semiconductor memory device according to claim 11, wherein the one side of the memory cell region is disposed in the vicinity of an edge of a chip and said another side of the memory cell region is disposed in the vicinity of the center of the chip.

13. The semiconductor memory device according to claim 12, further comprising a command circuit disposed in the vicinity of the center of the chip and for outputting the address signals and the command signals that select the memory cells in the memory cell region.

14. The semiconductor memory device according to claim 13, further comprising a data circuit disposed on the vicinity of the center of the chip and including an input-output buffer temporarily holding data input to or output from the memory cell region.

15. The semiconductor memory device according to claim 11, wherein the one side of the memory cell region is disposed in the vicinity of the center of a chip and said another side of the memory cell region is disposed in the vicinity of an edge of the chip.

16. The semiconductor memory device according to claim 15, further comprising a command circuit disposed in the vicinity of the center of the chip and outputs the address signals and the command signals for selecting the memory cells in the memory cell region.

17. The semiconductor memory device according to claim 16, further comprising a data circuit disposed on the vicinity of an edge of the chip and including an input-output buffer temporarily holding data input to or output from the memory cell region.
